(19) United States
(12) Patent Application Publication
(10) Pub. No.: US 2026/0064914 A1
(43) Pub. Date: Mar. 5, 2026

(54) SYSTEM AND METHOD FOR ANALYZING PERFORMANCE OF EXOSKELETON USING ARTIFICIAL INTELLIGENCE MODEL

(71) Applicant: ELECTRONICS AND TELECOMMUNICATIONS RESEARCH INSTITUTE, Daejeon (KR)

(72) Inventors: HyunSuk Kim, Daejeon (KR); Woojin Kim, Daejeon (KR); Daesub Yoon, Daejeon (KR); Mi CHANG, Daejeon (KR); Hyunwoo Joe, Daejeon (KR)

(21) Appl. No.: 18/989,944

(22) Filed: Dec. 20, 2024

(30) Foreign Application Priority Data
Aug. 28, 2024 (KR) 10-2024-0115541

(51) Int. Cl. G06F 30/27; B25J 9/00

(52) U.S. Cl. CPC G06F 30/27; B25J 9/0006

(57) ABSTRACT

Disclosed is a system for analyzing performance of an exoskeleton using an artificial intelligence model. The system for analyzing performance of an exoskeleton using an artificial intelligence model includes: an exoskeleton data measurement unit that measures usage data using a sensor attached to a muscle-enhancing wearable device, an exoskeleton data transmission unit that transmits data measured by the exoskeleton data measurement unit, an AI model management unit for performance analysis of an exoskeleton that generates an AI model for analyzing the performance of the exoskeleton, and an exoskeleton performance prediction unit that predicts the performance of the exoskeleton using the AI model.

### CROSS-REFERENCE TO RELATED APPLICATION

This application claims priority from and the benefit of Korean Patent Application No. 10-2024-0115541, filed on Aug. 28, 2024, which is hereby incorporated by reference for all purposes as if set forth herein.

### BACKGROUND

### 1. Field of the Invention

The present disclosure relates to a system and method for analyzing performance of an exoskeleton.

### 2. Description of Related Art

According to the related art, an upper or lower limb exoskeleton is being developed as a device for assisting human muscle strength to support effective gait rehabilitation training for patients with muscle damage or nervous system diseases.

According to the related art, there is a problem in that the performance evaluation of the exoskeleton device basically relies only on the subjective feeling of a wearer. Accordingly, an objective evaluation technique for the performance of the exoskeleton device is needed.

### SUMMARY

The present disclosure is proposed to solve the above-mentioned problem, and proposes a performance evaluation technique for an exoskeleton that may help with functional recovery and training level of upper or lower limb muscles. More specifically, the present disclosure provides a system and method for analyzing performance of an exoskeleton capable of providing more efficient and user-friendly assistance by measuring data from a load cell, a force sensing resistor (FSR), and angle, speed, and torque sensors of a motor before manufacturing an exoskeleton prototype for muscle strength enhancement or during actual use and after wearing an exoskeleton and by analyzing and evaluating arm movement or gait performance through artificial intelligence.

According to an embodiment of the present disclosure, a system for analyzing performance of an exoskeleton using an artificial intelligence model includes: an exoskeleton data measurement unit that measures usage data using a sensor attached to a muscle-enhancing wearable device; an exoskeleton data transmission unit that transmits data measured by the exoskeleton data measurement unit; an AI model management unit for performance analysis of an exoskeleton that generates an AI model for analyzing the performance of the exoskeleton; and an exoskeleton performance prediction unit that predicts the performance of the exoskeleton using the AI model.

The exoskeleton data measurement unit may measure the usage data related to an interaction force measured from a load cell, an FSR, and angle, speed, and torque sensors of a motor.

The exoskeleton data measurement unit may collect sensor data while the motors each are in on and off states, extract features of gait data, and integrate and store features of the gait data.

The exoskeleton data transmission unit may transmit the data to an exoskeleton performance analysis terminal or server.

The AI model management unit for performance analysis of an exoskeleton may analyze data features according to a motor state of a gait composed of swing and stance to generate the AI model.

The AI model management unit for performance analysis of an exoskeleton may perform a paired t-test for a motor off state and a motor on state, assign a class label, extract training data, and generate the AI model.

The AI model management unit for performance analysis of an exoskeleton may include a data collection and preprocessing unit, an exoskeleton sensing data DB, an AI model generation unit for performance analysis of an exoskeleton, and an exoskeleton performance determination unit, the data collection and preprocessing unit may collect and preprocess data including a load cell, an FSR, and an angle, speed, torque of the motor, and a motor operation state, the exoskeleton sensing data DB may store and manage the preprocessing results, the AI model generation unit for performance analysis of an exoskeleton may generate an AI model based on a load cell, an FSR, and an angle, speed, and torque of the motor, and the exoskeleton performance determination unit may integrate predicted values output using the AI model to provide a final performance determination result.

The exoskeleton performance prediction unit may receive data from a gait test performed while wearing the exoskeleton, apply the received data to the AI model to predict the performance, and provide the performance analysis result through a user interface.

The exoskeleton data measurement unit may collect sensor data when the motors each are in on and off states, extract data features of upper limb movement, and integrate and store the features of the upper limb movement data, and the AI model management unit for performance analysis of an exoskeleton may generate the AI model by analyzing the data features according to the motor state for the upper limb movement composed of flexion and extension.

According to another embodiment of the present disclosure, a method of analyzing performance of an exoskeleton using an artificial intelligence model includes: (a) acquiring data from a sensor attached to a muscle-enhancing wearable device; (b) generating an AI model for analyzing the performance of the exoskeleton using the data; and (c) performing the performance analysis of the exoskeleton using the AI model.

In step (a), the data related to an interaction force measured from a load cell, and an FSR, and angle, speed, and torque sensors of a motor may be acquired.

In step (a), the data may be acquired while the motors each are in on and off states, and features of arm movement data or gait data may be extracted, integrated, and stored.

In step (b), data features may be analyzed according to a motor state for arm movement composed of flexion and extension, or data features according to a motor state of a gait composed of swing and stance may be analyzed to generate an AI model.

In step (b), a test for a motor off state and a motor on state may be performed, and a class label may be assigned to extract training data.

In step (b), data including a load cell, an FSR, an angle, speed, and torque of the motor may be collected and preprocessed, and the motor operation state, and the AI model based on the load cell, the FSR, and the angle, speed, and torque of the motor may be generated.

In step (c), the AI model may be used to integrate predicted values output using the AI model and provide a final performance determination result.

### BRIEF DESCRIPTION OF DRAWINGS

FIG. 1 is a diagram illustrating a system for analyzing performance of an exoskeleton according to an embodiment of the present disclosure.

FIG. 2 is a diagram illustrating a process of collecting data used for the performance analysis of the exoskeleton according to an embodiment of the present disclosure.

FIG. 3 illustrates normalized load cell measurement data according to an embodiment of the present disclosure.

FIG. 4 illustrates training data used to generate a load cell-based AI model according to an embodiment of the present disclosure.

FIG. 5 illustrates a detailed configuration of an AI model management unit for performance analysis of an exoskeleton according to an embodiment of the present disclosure.

FIG. 6 is a diagram illustrating a process of predicting the performance of the exoskeleton according to an embodiment of the present disclosure.

FIG. 7 is a diagram illustrating a method of analyzing performance of an exoskeleton according to an embodiment of the present disclosure.

FIG. 8 is a block diagram illustrating a computer system for implementing the method according to the embodiment of the present disclosure.

### DETAILED DESCRIPTION

The above-described aspect, and other aspects, advantages, and features of the present disclosure and methods accomplishing them will become apparent from the following detailed description of exemplary embodiments with reference to the accompanying drawings.

However, the present disclosure may be modified in many different forms and it should not be limited to the exemplary embodiments set forth herein, and only the following embodiments are provided to easily inform those of ordinary skill in the art to which the present disclosure pertains the objects, configurations, and effects of the present disclosure, and the scope of the present disclosure is defined by the description of the claims.

Meanwhile, terms used in the present specification are for explaining exemplary embodiments rather than limiting the present disclosure. Unless explicitly described to the contrary, a singular form includes a plural form in the present specification. The terms “comprise” and/or “comprising” as used herein do not exclude the existence or addition of one or more other components, steps, operations, and/or elements in addition to the mentioned components, steps, operations, and/or elements.

An exoskeleton is a device that assists human muscle strength, helping users exert greater strength than they originally possess. Various types of upper or lower limb exoskeletons are being developed to enable patients with severe muscle damage or neurological diseases such as stroke, spinal cord injury, cerebral palsy, and Parkinson's disease to perform gait rehabilitation training more effectively.

According to the related art, there is a limitation in that performance evaluation of an exoskeleton device basically relies only on subjective feeling of a wearer. Even if the same assistive power is provided, some users may feel that the exoskeleton device is helpful, while others may evaluate it as not helpful. This is because each wearer interacts with and adapts to the exoskeleton device differently, and the interaction between the exoskeleton device and the wearer may be affected by various factors. For example, it may be affected by physical conditions of a wearer, the fit of the exoskeleton, user's experience and expectations, etc. In addition, the degree of the assistive power provided by the exoskeleton and how effectively the user may utilize the exoskeleton are also important factors.

Therefore, in relation to the performance of the exoskeleton device, it is necessary to introduce various objective indicators and evaluation methods rather than simply relying on the subjective evaluation of the wearer.

According to an embodiment of the present disclosure, by mounting devices such as a load cell, a force sensing resistor (FSR), and angle, speed, and torque sensors of a motor on the exoskeleton device, it is possible to observe a change in force exerted by a user, and by analyzing sensor information to analyze a change in force required to perform the operation after wearing the exoskeleton device, it is possible to more accurately determine operation assistance performance of the exoskeleton. Hereinafter, a lower limb exoskeleton that may assist gait performance will be described as a main example, and when expanded to an upper limb exoskeleton, it is also possible to analyze data features according to the motor state in the form of flexion and extension of an arm to generate an AI model, and perform the performance analysis of the exoskeleton using artificial intelligence.

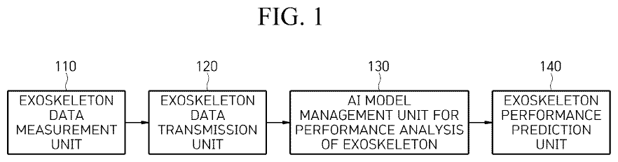

FIG. 1 illustrates a system for analyzing performance of an exoskeleton according to an embodiment of the present disclosure.

The system for analyzing performance of an exoskeleton according to an embodiment of the present disclosure includes an exoskeleton data measurement unit 110 that measures data from a muscle-enhancing wearable device, an exoskeleton data transmission unit 120 that transmits the measured data, an AI model management unit 130 for performance analysis of an exoskeleton that generates an AI model for performance analysis, and an exoskeleton performance prediction unit 140 that predicts exoskeleton performance using an AI model for performance analysis.

The exoskeleton data measurement unit 110 measures user's interaction force from the load cell, the FSR, and the angle, speed, and torque sensors of the motor mounted inside a muscle-enhancing wearable device worn by a user.

In the case of the lower limb exoskeleton, the load cell and the FSR sensor can be mounted in various locations such as a knee, a hip, a thigh, and a calf, and the motor can be mounted in various locations such as a waist and a hip joint.

In the case of the upper limb exoskeleton, the load cell, the FSR sensor, and the motor can be installed in various locations such as an elbow, a wrist, and a shoulder.

The exoskeleton data transmission unit 120 acts as a gateway between the muscle-enhancing wearable device and an exoskeleton performance analysis terminal or a server, and performs data transmission and reception functions.

The AI model management unit 130 for performance analysis of an exoskeleton is a terminal or server that analyzes the performance of the exoskeleton, stores and manages sensed information, and generates an AI model for performance analysis based on the sensed information.

The exoskeleton performance prediction unit 140 receives test data on arm movement or gait test data while wearing the exoskeleton, applies the received test data to the AI model to predict performance, and provides the performance analysis results to a user through various user interfaces (e.g., screens).

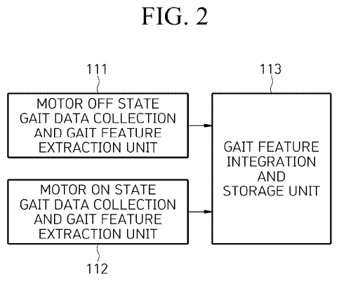

FIG. 2 is a diagram illustrating a process of collecting data used for the performance analysis of the exoskeleton according to an embodiment of the present disclosure.

The exoskeleton data measurement unit 110 collects training data or test data.

A motor off state gait data collection and gait feature extraction unit 111 collects various sensor data, such as the angle, speed, and torque of the motor, the load cell, and the FSR, from sensors mounted on an exoskeleton while a user wearing the exoskeleton walks a predetermined distance (e.g., 7 meters) with the motor in an off state, and extracts features from each gait data.

A motor on state gait data collection and gait feature extraction unit 112 collects various sensor data, such as the angle, speed, and torque of the motor, the load cell, and the FSR, from the sensors mounted on the exoskeleton while the user wearing the exoskeleton walks a predetermined distance (e.g., 7 meters) with the motor in an on state, and extracts the features from each gait data.

A gait feature integration and storage unit 113 integrates and stores gait feature information received from the motor off state gait data collection and gait feature extraction unit 111 and the motor on state gait data collection and gait feature extraction unit 112.

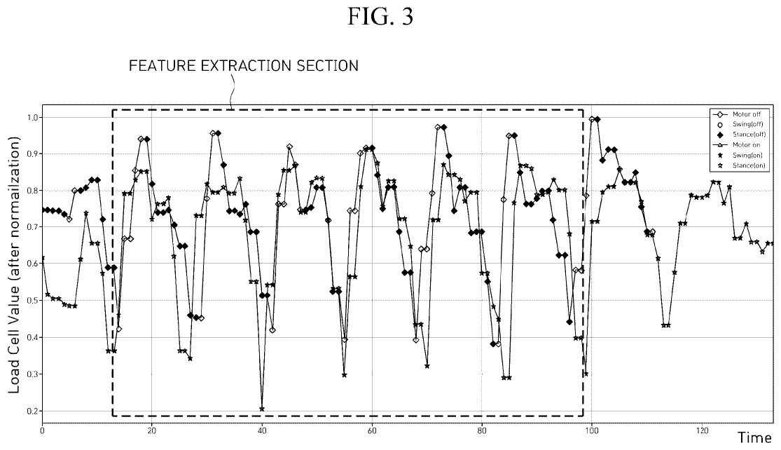

FIG. 3 illustrates normalized load cell measurement data according to an embodiment of the present disclosure, and describes a load cell of a lower limb exoskeleton as an example, but the scope of the present disclosure also includes performance analysis of an upper limb exoskeleton, not a lower limb exoskeleton.

FIG. 3 illustrates normalizing load cell data measured while gaiting for each user and comparing cases where the motor of the exoskeleton is turned off and on.

The gait is composed of swing and stance, and since data features for each gait, data features for each swing, and data features for each stance are different depending on the state of the motor, it is possible to analyze these data features and utilize the analyzed data features to evaluate the performance of the exoskeleton.

As described above, in the case of another embodiment (upper limb exoskeleton) of the present disclosure, it is possible to analyze the data features according to the motor state in the form of flexion and extension) and extending of an arm to generate an AI model and perform the performance analysis of the exoskeleton using AI.

That is, in the case of the upper limb exoskeleton, it is possible to collect and analyze data including the load cell, the FSR, and the angle, speed, and torque of the motor, and the motor operation state according to the arm movement (flexion and extension) in relation to the motor state of the on and off, and to generate an AI model based on the collected and analyzed data to evaluate the performance of the upper limb exoskeleton using the AI.

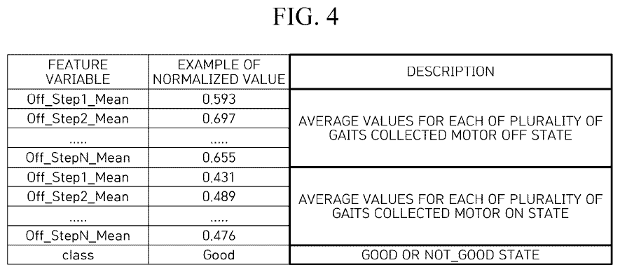

FIG. 4 illustrates training data used to generate a load cell-based AI model according to an embodiment of the present disclosure.

As described above with reference to FIG. 3, a user walks a preset distance (e.g., 7 meters) while the motor of the exoskeleton is turned off and on, and multiple gait data are acquired. The analysis is performed according to the motor state (i.e., according to the motor on/off state) in relation to the characteristics of an average value, a minimum value, a maximum value, and a range of the load cell of each gait.

When a paired t-test is performed on the motor off state and the motor on state, and the decrease in the load cell value in the motor on state is determined to be significant, the exoskeleton performance is determined to be effective for the user, and a class label is assigned as Good at this time.

When the paired t-test result is insignificant or the load cell value is determined to have increased in the motor on state even if the paired t-test result is significant, the motor assistance is determined to be ineffective for the user, and the class label is assigned as Not_Good at this time.

The above-described method is similarly applied to the swing and stance, and it is possible to extract and use the training data in the same way as described with reference to FIG. 4 for FSR-based AI model generation and motor angle/speed/torque-based AI model generation.

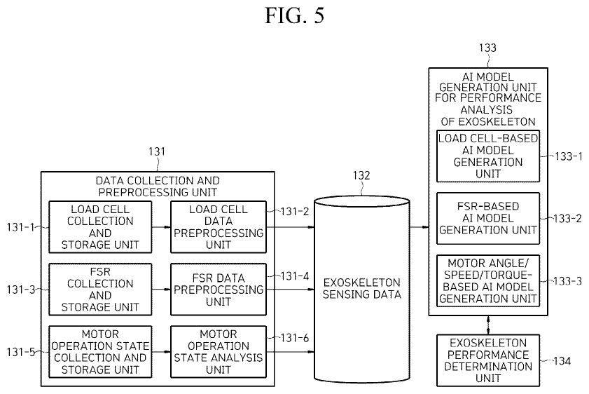

FIG. 5 illustrates a detailed configuration of an AI model management unit for performance analysis of an exoskeleton according to an embodiment of the present disclosure.

The AI model management unit 130 for performance analysis of an exoskeleton includes a data collection and preprocessing unit 131, an exoskeleton sensing data DB 132, an AI model generation unit for performance analysis of an exoskeleton 133, and an exoskeleton performance determination unit 134.

The data collection and preprocessing unit 131 collects data including the motor angle/speed/torque, the load cell, the FSR, and the motor operation state received from the exoskeleton data transmission unit 120, preprocesses the collected data, and stores the preprocessed data in a data storage.

A load cell collection and storage unit 131-1 collects load cell sensing information in real time, and a load cell data preprocessing unit 131-2 performs preprocessing on the data. The load cell may be mounted in various locations such as a hip and a knee, and the sensed load cell information is processed at each mounting location. The load cell data preprocessing unit 131-2 extracts features such as average, minimum, maximum, and range of each gait data, analyzes values corresponding to variables described in FIG. 4, and stores the preprocessing results in the exoskeleton sensing data DB 132.

The features such as average, minimum, maximum, and range are also extracted for the swing and stance sections, and stored in the exoskeleton sensing data DB 132.

The FSR collection and storage unit 131-3 collects FSR sensing information in real time and stores the collected FSR sensing information so that the FSR data preprocessing unit 131-4 may use the FSR sensing information. The FSR may be installed in various locations such as a thigh and a calf, and the sensed FSR information is processed at each installed location. The FSR data preprocessing unit 131-4 extracts the features of each gait data similarly to the load cell data preprocessing unit 131-2, analyzes values corresponding to variables described with reference to FIG. 4, and stores the preprocessing results in the exoskeleton sensing data DB 132.

A motor operation state collection and storage unit 131-5 collects information such as the on/off operation state, the angle, speed, and torque of the motor attached to the exoskeleton in real time and stores the collected information so that the motor operation state analysis unit 131-6 may use the collected information. The motor can be installed in various locations such as a back of a waist and a hip joint, and the motor information sensed for each installed location is processed.

The motor operation status analysis unit 131-6 extracts the features of each gait data as described with reference to FIG. 2, similar to the load cell data preprocessing unit 131-2 and the FSR data preprocessing unit 131-4, and analyzes the values corresponding to the variables as described with reference to FIG. 4, and stores the preprocessing results in the exoskeleton sensing data DB 132.

The AI model generation unit 133 for performance analysis of exoskeleton includes a load cell-based AI model generation unit 133-1, an FSR-based AI model generation unit 133-2, and a motor angle/speed/torque-based AI model generation unit 133-3.

The load cell-based AI model generation unit 133-1 generates an AI model capable of determining the performance of the exoskeleton using training data described with reference to FIG. 4 using a machine learning/deep learning algorithm targeting load cell data.

The FSR-based AI model generation unit 133-2 generates an AI model capable of determining the performance of the exoskeleton using FSR feature data.

The motor angle/speed/torque-based AI model generation unit 133-3 generates an AI model capable of determining the performance of the exoskeleton performance using motor operation feature data.

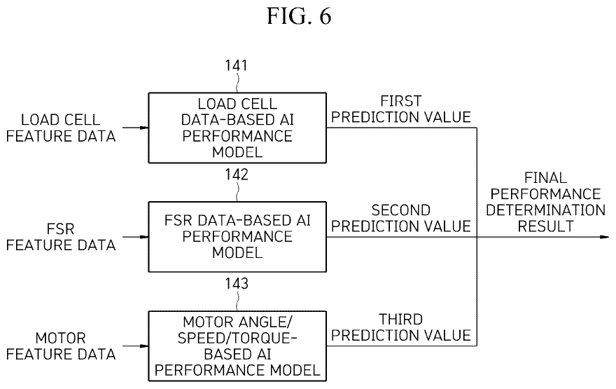

FIG. 6 is a diagram illustrating a process of predicting the performance of the exoskeleton according to an embodiment of the present disclosure.

The exoskeleton performance prediction unit 140 according to the embodiment of the present disclosure determines the performance for wearing the exoskeleton according to the procedure of predicting the performance of the exoskeleton.

The load cell feature data collected and analyzed while the user gaits is used as test data for a load cell data-based AI performance model 141 to acquire a first performance prediction value, the FSR feature data is used as test data for an FSR data-based AI performance model 142 to acquire a second performance prediction value, and the motor feature data is used as test data for a motor angle/speed/torque-based AI performance model 143 to acquire a third prediction value.

As described above, since a load cell sensor mounting position, an FSR sensor mounting position, and a motor position may vary, there may be a plurality of load cell data-based AI performance models 141, FSR data-based AI performance models 142, and motor angle/speed/torque-based AI performance models 143.

The final performance for wearing the exoskeleton is determined by combining a plurality of prediction values.

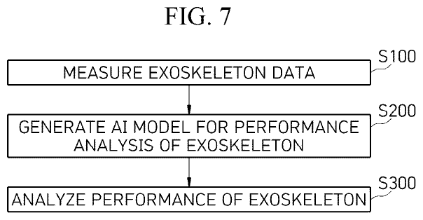

FIG. 7 is a diagram illustrating a method of analyzing performance of an exoskeleton according to an embodiment of the present disclosure.

The method of analyzing performance of an exoskeleton using an artificial intelligence model according to an embodiment of the present disclosure includes a step (S100) of acquiring data from a sensor attached to a muscle-enhancing wearable device, a step (S200) of generating an AI model for performance analysis of the exoskeleton using the data, and a step (S300) of performing performance analysis of the exoskeleton using the AI model.

Step S100 obtains data related to interaction forces measured from the load cell, the FSR, and the angle, speed, and torque sensors of the motor. Step S100 acquires data in the state where the motors are each on and off, and extracts, integrates, and stores features of arm movement data or gait data.

Step S200 analyzes data features according to a motor state for arm movement composed of flexion and extension, or analyzes data features according to a motor state of a gait composed of swing and stance to generate an AI model.

Step S200 performs a test for a motor off state and a motor on state, and extracts training data by assigning a class label.

Step S200 collects and preprocesses data including the load cell, the FSR, the angle, speed, and torque of the motor, and the motor operation state, and generates the AI model based on the load cell, the FSR, and the angle, speed, and torque of the motor.

Step S300 integrates the output prediction values using the AI model to generate the final performance determination result.

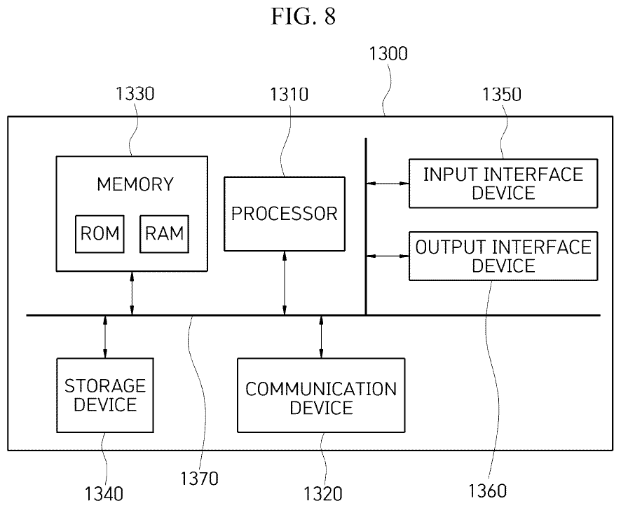

FIG. 8 is a block diagram illustrating a computer system for implementing the method according to the embodiment of the present disclosure.

Referring to FIG. 8, a computer system 1300 may include at least one of a processor 1313, a memory 1330, an input interface device 1350, an output interface device 1360, and a storage device 1340 that communicate through a bus 1370. The computer system 1300 may also include a communication device 1320 coupled to a network. The processor 1310 may be a central processing unit (CPU) or a semiconductor device that executes commands stored in the memory 1330 or the storage device 1340. The memory 1330 and the storage device 1340 may include various types of volatile or non-volatile storage media. For example, the memory may include a read only memory (ROM) and a random access memory (RAM). In the embodiment of the present disclosure, the memory may be located inside or outside the processing unit, and the memory may be connected to the processing unit through various known means. The memory may be various types of volatile or non-volatile storage media, and the memory may include, for example, a ROM or a RAM.

Accordingly, the embodiment of the present disclosure may be implemented as a computer-implemented method, or as a non-transitory computer-readable medium having computer-executable instructions stored thereon. In one embodiment, when executed by the processing unit, the computer-readable instructions may perform the method according to at least one aspect of the present disclosure.

The communication device 1320 may transmit or receive a wired signal or a wireless signal.

In addition, the method according to the embodiment of the present disclosure may be implemented in a form of program instructions that may be executed through various computer means and may be recorded in a computer-readable recording medium.

The computer-readable recording medium may include program commands, data files, data structures or the like, alone or a combination thereof. The program instructions recorded in the computer-readable recording medium may be configured by being especially designed for the embodiment of the present disclosure, or may be used by being known to those skilled in the field of computer software. The computer-readable recording medium may include a hardware device configured to store and execute the program instructions. Examples of the computer-readable recording medium may include a magnetic medium such as a hard disk, a floppy disk, and a magnetic tape, an optical medium such as a compact disk read only memory (CD-ROM) or a digital versatile disk (DVD), a magneto-optical medium such as a floptical disk, a ROM, a RAM, a flash memory, or the like. Examples of the program instructions may include a high-level language code capable of being executed by a computer using an interpreter, or the like, as well as a machine language code made by a compiler.

According to the present disclosure, it is possible to previously evaluate the performance of the exoskeleton device in the machine learning/deep learning manner using the information from the load cell, the force sensing resistor (FSR), the angle, speed, and torque sensors of the motor.

According to the present disclosure, it is possible to evaluate the performance of the exoskeleton device more objectively and reliably, and to utilize the exoskeleton device to provide the customized assistive power that meets the needs and conditions of each wearer. By improving the evaluation method, it is possible to maximize the effect of the rehabilitation treatment, provide more efficient and effective rehabilitation solutions to various patients through the customized rehabilitation programs according to the conditions and needs of each patient, and promote the growth of the industry of the wearable device for muscle strength enhancement.

The effects of the present disclosure are not limited to those mentioned above, and other effects not mentioned can be clearly understood by those skilled in the art from the following description.

Although embodiments of the present disclosure have been described in detail hereinabove, the scope of the present disclosure is not limited thereto, but may include several modifications and alterations made by those skilled in the art using a basic concept of the present disclosure as defined in the claims.

What is claimed is:

1. A system for analyzing performance of an exoskeleton using an artificial intelligence (AI) model, comprising:
an exoskeleton data measurement unit that measures usage data using a sensor attached to a muscle-enhancing wearable device;
an exoskeleton data transmission unit that transmits data measured by the exoskeleton data measurement unit;
an AI model management unit for performance analysis of an exoskeleton that generates an AI model for analyzing the performance of the exoskeleton; and
an exoskeleton performance prediction unit that predicts the performance of the exoskeleton using the AI model.

2. The system of claim 1, wherein the exoskeleton data measurement unit measures the usage data related to an interaction force measured from a load cell, an FSR, and angle, speed, and torque sensors of a motor.

3. The system of claim 2, wherein the exoskeleton data measurement unit collects sensor data while the motors each are in on and off states, extracts a feature of gait data, and integrates and stores features of the gait data.

4. The system of claim 1, wherein the exoskeleton data transmission unit transmits the data to an exoskeleton performance analysis terminal or server.

5. The system of claim 1, wherein the AI model management unit for performance analysis of an exoskeleton analyzes data features according to a motor state of a gait composed of swing and stance to generate the AI model.

6. The system of claim 5, wherein the AI model management unit for performance analysis of an exoskeleton performs a paired t-test for a motor off state and a motor on state, assigns a class label, extracts training data, and generates the AI model.

7. The system of claim 6, wherein the AI model management unit for performance analysis of an exoskeleton includes a data collection and preprocessing unit, an exoskeleton sensing data DB, an AI model generation unit for performance analysis of an exoskeleton, and an exoskeleton performance determination unit,
the data collection and preprocessing unit collects and preprocesses data including a load cell, an FSR, and an angle, speed, torque of the motor, and a motor operation state,
the exoskeleton sensing data DB stores and manages the preprocessing results,
the AI model generation unit for performance analysis of an exoskeleton generates an AI model based on a load cell, an FSR, and an angle, speed, and torque of the motor, and
the exoskeleton performance determination unit integrates predicted values output using the AI model to provide a final performance determination result.

8. The system of claim 1, wherein the exoskeleton performance prediction unit receives data from a gait test performed while wearing the exoskeleton, applies the received data to the AI model to predict the performance, and provides the performance analysis result through a user interface.

9. The system of claim 1, wherein the exoskeleton data measurement unit collects sensor data when the motors each are in on and off states, extracts data features of upper limb movement, and integrates and stores the features of the upper limb movement data, and the AI model management unit for performance analysis of an exoskeleton generates the AI model by analyzing the data features according to the motor state for the upper limb movement composed of flexion and extension.

10. A method of analyzing performance of an exoskeleton using an artificial intelligence (AI) model, comprising:
(a) acquiring data from a sensor attached to a muscle-enhancing wearable device;
(b) generating an AI model for analyzing the performance of the exoskeleton using the data; and
(c) performing the performance analysis of the exoskeleton using the AI model.

11. The method of claim 10, wherein in step (a), the data related to an interaction force measured from a load cell, and an FSR, and angle, speed, and torque sensors of a motor is acquired.

12. The method of claim 11, wherein in step (a), the data is acquired while the motors each are in on and off states, and features of arm movement data or gait data are extracted, integrated, and stored.

13. The method of claim 10, wherein in step (b), data features are analyzed according to a motor state for arm movement composed of flexion and extension, or data features according to a motor state of a gait composed of swing and stance are analyzed to generate an AI model.

14. The method of claim 13, wherein in step (b), a test for a motor off state and a motor on state is performed, and a class label is assigned to extract training data.

15. The method of claim 14, wherein in step (b), data including a load cell, an FSR, an angle, speed, and torque of the motor is collected and preprocessed, and the motor operation state, and the AI model based on the load cell, the FSR, and the angle, speed, and torque of the motor is generated.

16. The method of claim 15, wherein in step (c), the AI model is used to integrate predicted values output using the AI model and provide a final performance determination result.
